(19) United States
(12) Patent Application Publication
(10) Pub. No.: US 2025/0140592 A1
(43) Pub. Date: May 1, 2025

(54) METHOD AND SYSTEM FOR DIE BONDING

(71) Applicant: CANON KABUSHIKI KAISHA, Tokyo (JP)

(72) Inventors: Nilabh K ROY, Austin, TX (US); Byung-Jin CHOI, Austin, TX (US)

(21) Appl. No.: 18/495,368

(22) Filed: Oct. 26, 2023

(51) Int. Cl. H01L 21/68; H01L 21/67; H01L 21/687; H01L 23/00

(52) U.S. Cl. CPC H01L 21/681; H01L 21/67144; H01L 21/68764; H01L 24/75; H01L 24/81; H01L 24/95; H01L 2224/75702; H01L 2224/75804; H01L 2224/75824; H01L 2224/81121; H01L 2224/95121; H01L 2924/40

(57) ABSTRACT

A bonding method includes providing a source substrate, the source substrate includes active side alignment marks on an active side of the source substrate, first non-active side alignment marks and second non-active side alignment marks on a non-active side of the source substrate, and obtaining positions of the active side alignment marks and positions of the first non-active side alignment marks of the source substrate, and determining alignment marks placement errors based on offsets between the positions of the active-side alignment marks and the positions of the first non-active side alignment marks in the X, Y, and θ directions.

### BACKGROUND

### Field

The present disclosure relates to a bonding system and a bonding method.

### Description of the Related Art

Advanced packaging technologies demand high throughput and precise placement of chips. Hybrid bonding can be particularly challenging with small misalignment tolerances.

In a flip chip to wafer bonding process, alignment metrology is often carried out through an off-axis measurement scheme where the die position on the chuck is obtained before the bonding step begins and then the chip is bonded to the substrate in passive alignment. Further, the achievable accuracy with existing flip chip bonders is not very high (>200 nm). Aligning die with wafer in a heterogeneous 3D packaging equipment within <100 nm overlay accuracy is difficult.

One of the key challenges in the process is the placement of the dies from the die chuck to the product wafer with high overlay accuracy so that the active side of dies are placed on the transfer wafer within an acceptable error bound. To enable good placement accuracy, a metrology system is needed that can provide die placement feedback to the actuators on the die chuck and adjust its position and angular orientation when it is being transferred to the product wafer or substrate.

A need exists for a high throughput placement while still meeting specifications for chip placement.

### SUMMARY

According to an aspect of the present disclosure, a bonding method includes providing a source substrate, the source substrate includes active side alignment marks on an active side of the source substrate, first non-active side alignment marks and second non-active side alignment marks on a non-active side of the source substrate, and obtaining positions of the active side alignment marks and positions of the first non-active side alignment marks of the source substrate, and determining alignment marks placement errors based on offsets between the positions of the active-side alignment marks and the positions of the first non-active side alignment marks in the X, Y, and 0 directions.

Further features of the present disclosure will become apparent from the following description of exemplary embodiments with reference to the attached drawings.

### BRIEF DESCRIPTION OF THE DRAWINGS

FIG. 1 is a cross-sectional view showing a configuration of a bonding apparatus according to an embodiment of the present disclosure.

FIGS. 2A and 2B illustrate an example of an active side of and a non-active side of a source substrate, respectively.

FIG. 3 illustrates an example of a non-active side of a source substrate.

FIG. 4 illustrates an exemplary configuration for measuring alignment marks of the source substrate.

FIGS. 5A and 5B include a process flow diagram for a method of transferring and bonding dies to bonding sites of a destination substrate.

FIG. 6 illustrates a cross-sectional view of the apparatus of FIG. 1 after an array of pick-up heads picked up a set of dies from a holding substrate.

FIG. 7 illustrates a cross-sectional view of the apparatus of FIG. 1 for die alignment measurement operation.

FIG. 8 illustrates a cross-sectional view of the bonding apparatus of FIG. 1 for determining bonding head alignment error.

FIG. 9 illustrates another cross-sectional view of the apparatus of FIG. 1 for determining bonding head alignment error.

FIG. 10 is a block diagram illustrating an exemplary configuration of the metrology and alignment hardware.

It shall be understood that elements in the figures are illustrated for simplicity and clarity and have not necessarily been drawn to scale. For example, the dimensions of some of the elements in the figures can be exaggerated relative to other elements to help improve understanding of implementations of the disclosure.

### DESCRIPTION OF THE EMBODIMENTS

Hereinafter, exemplary embodiments of the present disclosure will be described in detail with reference to the accompanying drawings. The following exemplary embodiments are not intended to limit the present disclosure set forth in the appended claims, and not all combinations of features described in the exemplary embodiments are necessarily indispensable to solving means of the present disclosure. The same reference numerals denote similar constituent elements, and a description thereof will be omitted.

The bonding method is not limited to a specific bonding method. For example, the bonding method may be bonding using an adhesive, bonding by hybrid bonding, atomic diffusion bonding, vacuum bonding, bump bonding or the combination of the like.

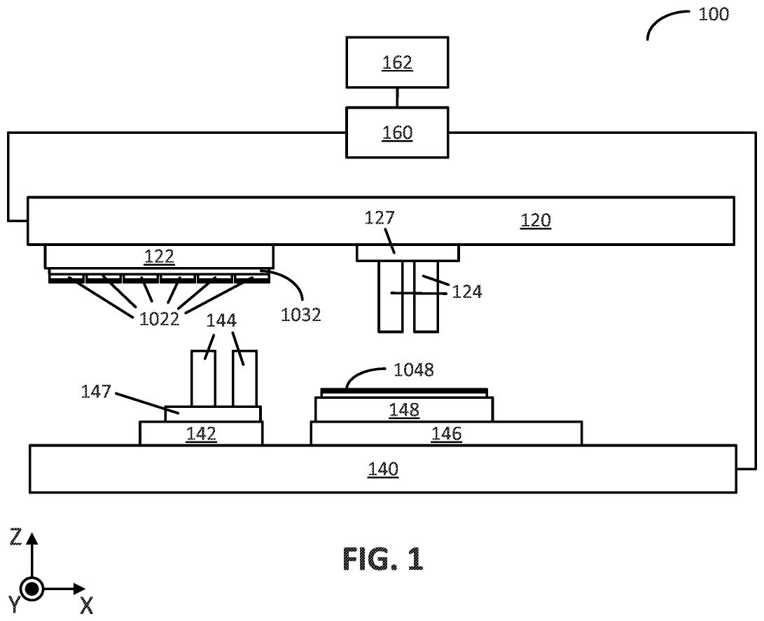

FIG. 1 is a schematic view illustrating the bonding apparatus 100 in accordance with an embodiment of the present disclosure. In FIG. 1, directions are indicated by an XYZ coordinate system. Typically, an XY plane is a plane parallel to the horizontal plane, and a Z-axis is an axis parallel to the vertical direction. X-, Y-, and Z-axes are examples of directions that are orthogonal to each other or cross each other. This also applies to the other drawings. Bonding apparatus 100 can be used to transfer dies from a holding substrate 1032 coupled to a source chuck 122 to a destination substrate 1048 coupled to a destination chuck 148. The holding substrate 1032 may be a dicing tape frame, a tape frame, a tray with pockets for die, a tape reel, a silicon wafer, a glass wafer, a plastic sheet, or any suitable structure for temporarily holding a plurality of dies prior to them being placed on an array of bonding heads 124. The destination substrate 1048 may be a silicon wafer, a silicon wafer on which wirings are formed, a glass wafer, a glass panel on which wirings are formed, a printed wiring board, or the like. The bonding apparatus 100 includes a bridge 120, a base 140, and a controller 160 that is coupled to the bridge 120, the base 140, or to one or more components coupled to the bridge 120 or the base 140. The bridge 120 can be coupled to a source chuck 122, an array of bonding heads 124, and metrology and alignment hardware 127 and 147 are used for performing metrology and determining placement errors and adjusting alignment of a substrate or die(s). The base 140 can be coupled to a pick-up head carriage 142 and a destination carriage 146. In an alternative embodiment, there may be a single carriage on which all of the components which would be coupled to the pick-up head carriage 142 and the destination carriage 146 are coupled.

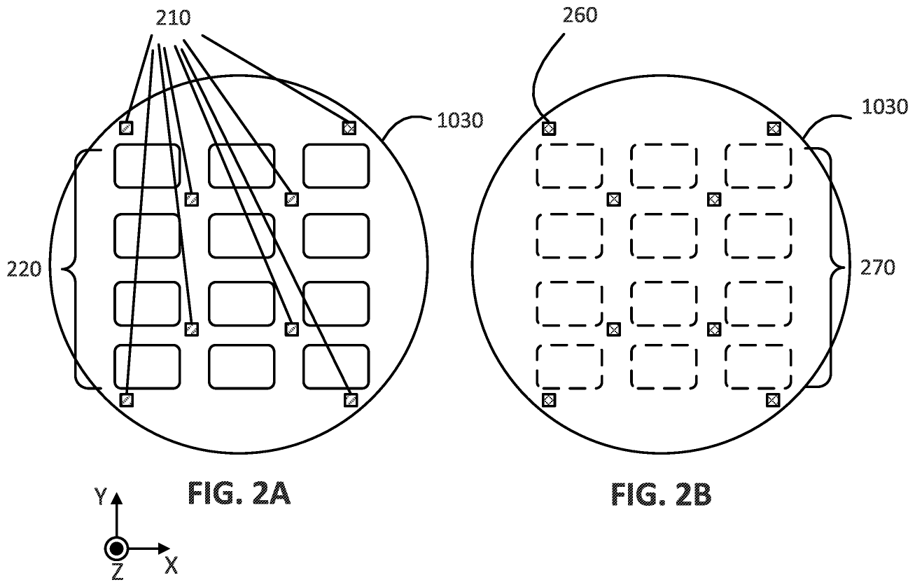

As shown in FIG. 1, a holding substrate 1032 including an array of dies is placed on the source chuck 122 with active side facing downward. The holding substrate 1032 is fabricated by first fabricating a source substrate 1030 as illustrated in FIGS. 2A and 2B. The source substrate 1030 may be fabricated using multiple known semiconductor processes including but not limited to lithography, etching doping, deposition, planarization, cleaning, polishing, thermal treatment, ion implantation, chemical vapor deposition, metrology, electrical testing, optical testing, drilling, or any other processes used for fabricating semiconductor, MEMS, or opto-electronic devices. The source substrate 1030 includes forming 10s, 100s; 1000s or 10,000s of identical die on the source substrate 1030. The source substrate 1030 has an active side (FIG. 2A) on which bonding pads, electrical circuits, and other features are formed and a non-active side opposite to the active side (FIG. 2B). The non-active side of the source substrate 1030 may include features such as through silicon vias (TSV). The source substrate 1030 may be attached to support material (not shown) such as a dicing tape, a protective material, a backing tape, a thinning tape, a support substrate, or any other material that provides mechanical support during subsequent operations.

FIGS. 2A and 2B show an active side and the opposite non-active side of the source substrate 1030 prior to a singulation process, respectively, in accordance with an embodiment of the present disclosure. An array of dies 220 are fabricated on the active side of the source substrate 1030. As shown in FIG. 2A, a set of active side alignment marks 210 are fabricated on the unused area (non-die area) of the source substrate 1030. While an array of 3×4 is shown in FIG. 2A, the array of dies can be arranged in other patterns. The active side alignment marks 210 can be dispersed in any pattern so long as the marks are fabricated in the unused portion of source substrate 1030. In an alternative embodiment, some but not all of the active side alignment marks are fabricated in the unused portion of the source substrate 1030. In some embodiments, alignment marks on the active side of source substrate 1030 are prefabricated in the source substrate 1032. These active side alignment marks 210 are representative of the alignment of the circuit/features on the active side.

Based on the positions of the set of active-side alignment marks 210, a set of corresponding non-active side alignment marks 260 are fabricated on the non-active side (backside) of the source substrate 1030 as illustrated in FIG. 2B. These non-active side alignment marks 260 are placed on the non-active side which are collinear with the active side alignment marks 210.

Before the non-active side alignment marks 260 are made and the metrology information is obtained and stored in memory 162, the non-singulated source substrate 1030 can be thinned down, if necessary, to a desired thickness of for example less than 0.1 mm. The thinning techniques may be performed using one or more back grinding processes such as mechanical grinding, chemical mechanical planarization (CMP), wet etching, dry etching, plasma etching, or any other process of removing material in a controlled manner. The thinning process may, for example, be performed by a DGP8761 fully automatic Grinder/Polisher from DISCO Corporation of Tokyo, Japan.

Alignment marks may then be formed on the non-active side of the thinned source substrate 1030. In an alternative embodiment, the alignment marks 260 are formed on the non-active side of the source substrate 1030 before thinning to a final thickness. In yet another embodiment, the alignment marks 260 are formed on the non-active side of the source substrate 1030 and the thinning process is not performed on the source substrate 1030. Formation of the alignment marks can be done using standard lithography techniques, which may include coating the non-active side with the alignment mark material such as coating the alignment mark material with a resist, patterning the resist, etching the resist, and removing the remaining resist. The alignment mark material may be any material that forms a contrast with the substrate material such as aluminum, chrome, gold, silver, etc. The patterning of the resist may be done with, for example, using a FPA-5520iV i-line stepper from Canon Inc., of Tokyo, Japan. When patterning a resist, a mask may be used which includes non-active side alignment marks in the unused area that coincide with the active side alignment marks and a set of die alignment marks that are within periphery of each of the die. In an alternative embodiment, maskless patterning is used to pattern the resist. In another embodiment a resist is not used, and laser etching is used to pattern the alignment mark material. In yet another embodiment, the alignment marks are formed using a direct printing technique in which a contrasting material is printed directly onto the first substrate. In yet another embodiment, the alignment marks are formed using a direct marking technique in which the substrate material is modified directly via optical or chemical means. Once the non-active side alignment marks are fabricated in both the unused areas and the die areas, the placement error of the marks in the unused area may be measured.

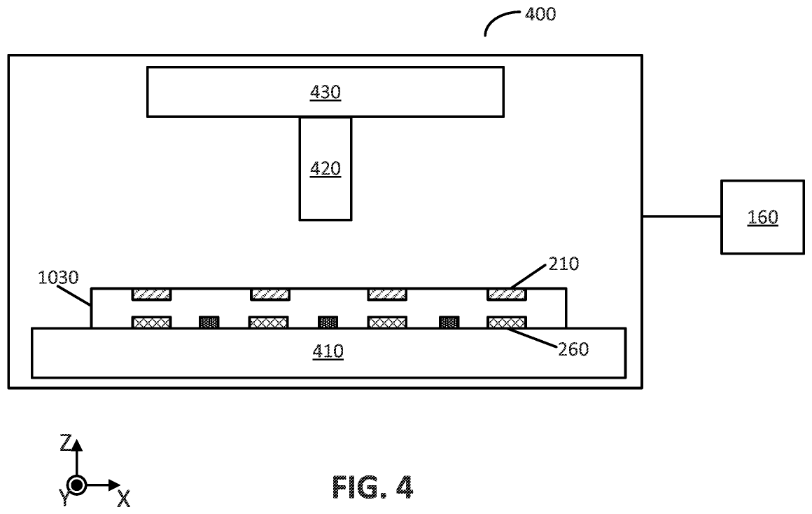

FIG. 4 is an exemplary configuration for measuring alignment marks of the source substrate 1030. In this example, the measurement system 400 is set up outside of bonding apparatus 100. In another embodiment, the measurement system 400 is incorporated within the bonding apparatus 100. The measurement system 400 can be controlled by controller 160 of FIG. 1 or controlled by another controller in communication with controller 160. According to FIG. 4, source substrate 1030 is placed on a substrate stage 410 with active side facing upward. The substrate stage 410 is capable of moving the source substrate in the X, Y, Z and/or tilt directions. The active side of the source substrate 1030 having a set of active side alignment marks 210 and the non-active side having a set of non-active side alignment marks 260. Thereafter, metrology can be performed by using an optical device 420 such as a microscope, camera, or beam splitter that is capable of seeing through the source substrate 1030. This may include an Infrared (IR) microscope or a vision system to look through IR transparent substrates. The optical device can be coupled to a movable holding device 430. The optical device 420 performs metrology to obtain positional information of the active side alignment marks 210 and non-active side alignment marks 260 and compares them against each other to obtain the X-direction error information and the Y-direction error information or the X-direction error information, Y-direction error information, and rotation (0) error information and provides the measurement result to the controller 160 or to a processor (not shown) connected to the controller 160 via a network. To enable observing both sets of marks 210 and 260, either the substrate stage 410 can move in Z-axis direction or the optical device 420 can use a Z-motion stage (not shown), which may be part of the holding device 430, to move the optical device in the Z-axis direction. Alternatively, the depth of field of the optical device 420 could be designed such that both sets of marks 210 and 260 produce good contrast at a single relative location of the optical device to the substrate i.e. the depth of field of the optical device is large enough that both sets of marks 210 and 260 are in focus at a single location, In an alternative embodiment, the optical device 420 is not capable of seeing through the source substrate 1030 and the source substrate 1030 is instead flipped over and the positional information of the of the active side alignment marks 210 and non-active side alignment marks 260 are obtained independently and make use of a global fiducial on both sides of the substrate to minimize any errors due to flipping.

Based on the measurement result, the controller 160 determines the alignment marks placement errors in the X, Y, and θ (rotational) directions based on the offset between the measured positions of the active-side alignment marks 210 and non-active-side alignment marks 260 on the source substrate 1030, where

$${Error}_{AlignmentMarks} ( i ) = \{ {e}_{{x}_{fronttoback}} ( i ) , {e}_{{y}_{fronttoback}} ( i ) , {e}_{{θ}_{fronttoback}} ( i ) \} . \qquad ( 1 )$$

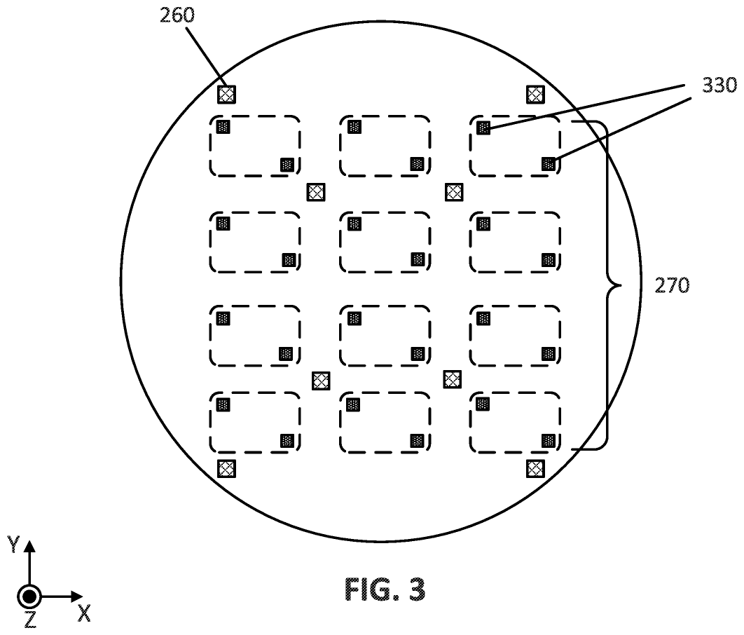

The Error_{AlignmentMarks}(i) is a measured placement error for each alignment mark (i) for a plurality of alignment marks 210 and 260 on the source substrate 1030 at a specific position (x, y). In one embodiment, the alignment marks may be thin marks that only allow measurement of the placement error in one or two of the dimensions {e_{xfronttoback}, e_{yfronttoback}, e_{θfronttoback}}. The full set of Error_{AlignmentMarks} may be fitted to a model f that describes the placement error (eₓ,e_{y},e_{θ}) of the alignment marks across the source substrate 1030 as a function of the mark location on the source substrate. The model f may also take into account the type of errors associated with the fabrication technique used to fabricate the marks. The model f may then be used to estimate the second alignment marks placement error 330 of FIG. 3 on the non-active side of the dies. A simple model f, which may be useful when there is a high density of alignment marks, and the errors are small, is to take a local average of the nearest alignment marks. In another embodiment, a model which takes into account additional high spatial frequency errors such as magnification, skew, trapezoidal and high order polynomials could also be included as offsets and correction to die alignment control algorithm. In another embodiment, a linear least squares fitting may be performed to fit n-th degree polynomial of the model f in two dimensions to the error data.

In particular, the source substrate 1030 has a set of active side alignment marks 210 (A). There are N active side alignment marks Aⱼ in the set of active side alignment marks 210 (A={A₁, . . . Aⱼ, . . . A_{N}}). Each active side alignment mark j is located at an active side alignment mark position Aⱼ on the active side of the source substrate 1030. Active side alignment mark position Aⱼ includes a position {A_{j,x}, A_{j,y}} in the coordinate system of the substrate (Aᵢ={A_{j,x}, A_{j,y}}).

The non-active side of the source substrate is patterned with a set of corresponding non-active side alignment marks 260 (B) and set of die alignment marks 330 (C). There are N non-active side alignment marks Bⱼ in the set of non-active side alignment marks 260 (B={B₁, . . . Bⱼ, . . . B_{N}}). Each non-active side alignment mark j is located at non-active side alignment mark position Bⱼ on the non-active side of the source substrate 1030. Ideally, the non-active side alignment mark positions Bⱼ should be collinearly located with active side alignment mark positions Aⱼ but on the back side of the substrate and they may have placement errors relative to active side alignment mark positions Aⱼ. The non-active side alignment mark position Bⱼ includes a position {B_{j,x}, B_{j,y}} in the coordinate system of the substrate (Bⱼ={B_{j,x}, B_{j,y}}).

Referring to FIG. 3, there are M die alignment marks in the set of die alignment marks 330 (C={C₁, . . . Cᵢ, . . . C_{M}}). Each die alignment mark i is located at die alignment mark position Cᵢ on the non-active side of the source substrate 1030. The die alignment mark position Cᵢ includes a position {C_{i,x}, C_{i,y}} in the coordinate system of the substrate (Cᵢ={C_{i,x}, C_{i,y}}). There is at least one die alignment mark 330 for each die on the source substrate 1030.

A set of positioning errors ΔP is obtained based on measuring the sets A and B or measuring the difference between the sets A and B analyzing crossed gratings of the corresponding alignment marks. There are N positioning errors ΔPⱼ in the set of positioning errors (ΔP={ΔP₁, . . . ΔPⱼ, . . . ΔP_{N}}). Each positioning error includes the measurement error in each axes (ΔPⱼ={A_{j,x}−B_{j,x},A_{j,y}−B_{j,y}}). If crossed gratings are used to obtain the positioning error then each positioning error may also include rotation (ΔPⱼ={A_{j,x}−B_{j,x},A_{j,y}−B_{j,y}θⱼ}).

A model f is created that describes how ΔP is related to active side alignment marks A nominal position (ΔP=f(k,A)+ε) based on a set of fitting parameters k that minimize an error ¿. The model f may be a series of steps in a process, a formula, a series of formulas. The set of fitting parameters k are calculated using standard model fitting techniques such as least squares fitting. Once a set of fitting parameters k is known then the model f may be used to calculate the die mark (second alignment mark) placement error for die alignment mark i using the nominal die mark location Cᵢ (Error_{AlignmentMarks2} (i)=f(k,Cᵢ)), it may also be used to calculate a set of die mark placement errors for the set of die alignment marks 330 (Error_{AlignmentMarks2}=f(k,C)).

FIG. 3 illustrates the non-active side of a source substrate 1030 including non-active side alignment marks 260 as illustrated in FIG. 2B, with additional die alignment marks 330 fabricated on the non-active side of each of the dies. As shown in FIG. 3, at least two die alignment marks are fabricated within the area of the non-active side of each die. However, each die may include more than 2 alignment marks on its non-active side. In this example, die alignment marks are fabricated on the opposite corners of each die. It shall be understood that the alignment marks can be placed in any area within the die periphery or boundary. The die alignment marks 330 and the bonding head alignment marks 710 may include complementary Moiré interference marks of one or more two-dimensional diffraction gratings. It may also be cross alignment marks, box in box, bar-in-bar, bullseye marks, edge alignment marks, serpentine marks, etc. The die alignment marks 330 are fabricated at the same time as the non-active side alignment marks 210 on the non-active surface of the source substrate 1030. This ensures that the placement errors of the die alignment marks 330 can be interpolated or modeled from the measurement of non-active side alignment marks 210 set.

The source substrate 1030 is then diced (singulated) into individual dies after the measurement. Prior to singulation, the support material of source substrate 1030 may be removed, and a dicing tape is added to the source substrate 1030. In an embodiment, the dicing tape is attached to the non-active side of the source substrate 1030. In an alternative embodiment, the support material is the dicing tape. The source substrate 1030 may then be subjected to a singulation process (singulating) in which the source substrate 1030 is diced. Singulating the source substrate 1030 will destroy, make unusable for alignment, or make unreadable for purposes of alignment the set of active side alignment marks 210 and the set of corresponding non-active side alignment marks 260. However, singulating the source substrate 1030 will have minimal impact on the set of die alignment marks 330 for purposes of alignment.

One or more machines may be involved in the dicing process in which the unused areas are removed leaving an array of dies on the tape frame. The singulation process may be performed with one or more of: a mechanical dicing saw; a laser saw; a waterjet saw; a scriber; and an etcher. After the singulation process, a die separator may be used to stretch the tape frame so that there is a larger separation between individual die on the tape frame. The die separator may heat up the tape frame and stretch it by 1%-20%. After the dies have been separated, the dies may be transferred to a holding substrate 1032 or the tape frame may act as the holding substrate 1032. After this the dies have been singulated, the dies may be cleaned and activated for the hybrid bonding process. Activating the dies may include, for example, treating the die with deionized water and a plasma. In an alternative embodiment, the dies are activated while on the on the bonding head 124 or the pick-up head 144.

Returning to FIG. 1, the bridge 120, the base 140, and components physically coupled between the bridge 120 or the base 140 can be organized along an X-direction, a Y-direction, a Z-direction, or a combination thereof. With respect to cross-sectional or side views of the bonding apparatus 100, the X-direction is between the left-hand and right-hand sides of the drawings, the Z-direction is between the top and bottom of the drawings, and the Y-direction is into and out of the drawing sheet. Unless explicitly stated to the contrary, rotation occurs along an X-Y plane defined by the X-direction and the Y-direction.

Components within the bonding apparatus 100 will be generally described in the order in which a set of dies will be transferred from a holding substrate 1032 coupled to the source chuck 122 to a destination substrate 1048 coupled to the destination chuck 148. Due to similarities in operation, the pick-up head carriage 142 and the destination carriage 146 are described in the same passage later in this specification.

The terms “transfer operation” and “transfer cycle” are addressed to aid in understanding embodiments as described herein. A transfer operation starts no later than picking up a set of dies from the source substrate, where the set of dies will be the first set of dies associated with the source substrate bonded to the destination substrate and ends when the last set of dies is transferred from the source substrate to the destination substrate. A transfer cycle starts no later than with picking up a particular set of dies from the source substrate until that same particular set of dies is transferred to the destination substrate. A transfer operation can include one or more transfer cycles.

The source chuck 122 can be a vacuum chuck, a pin-type chuck, a groove-type chuck, an electrostatic chuck, an electromagnetic chuck, or the like. The source chuck 122 can be coupled to the bridge 120 by being attached to the bridge directly or can be coupled to the bridge via a carriage (not illustrated). The carriage may be able to provide translation and/or rotation motion as described in more detail below with respect to the pick-up head carriage 142 and the destination carriage 146. The source chuck 122 has a chucking surface 123 that faces the base 140 or a component coupled to the base 140.

In FIG. 1, the pick-up head carriage 142 and the destination carriage 146 are coupled to the base 140 and can provide translating motion along the base 140 in the X-direction, the Y-direction, the Z-direction and/or rotational motion about one or more of axes, such as rotation about a Z-axis and along a plane lying along the X-direction and Y-direction. The pick-up head carriage 142 and the destination carriage 146 can be moved together or independently relative to each other. The pick-up head carriage 142 and the destination carriage 146 can be the same type or different types of carriages.

The array of pick-up heads 144 are coupled to the pick-up head carriage 142 and have pick-up chucks (not shown) that face the bridge 120 or a component coupled to the bridge 120. At least one of the pick-up heads 144 has a body where the body is disposed between such pick-up head carriage 142. In an alternative embodiment, the pick-up head carriage 142 and the destination carriage 146 may be unified into a single carriage.

The array of pick-up heads 144 can be configured as a vector (a row or a column of pick-up heads) or as a matrix (at least two rows and at least two columns of pick-up heads). Regarding the matrix, the number of pick-up heads within the array of pick-up heads 144 may be different between rows, between columns, or between rows and columns. Some array configurations can be 3×1, 6×1, 2×2, 2×3, 2×4, 10×10, or another rectangular shape, where the first number corresponds to the number of pick-up heads along a row or column, and the second number corresponds to the number of pick-up heads along the other of the row or column. In theory, dies from an entire holding substrate 1032 could be transferred all at once. For such a configuration, the array of pick-up heads 144 may have fewer pick-up heads along rows closer to the top and bottom of the array as compared to the row or the pair of rows closest to the center of the array, and the array of pick-up heads 144 may have fewer pick-up heads along columns closer to the left-hand side and right-hand side of the array as compared to the column or the pair of columns closest to the center of the array.

In an embodiment, a signal from the bridge 120, base 140, or any one or more components coupled to the bridge 120 or base 140 can be transmitted to the controller 160. For example, after the array of pick-up heads 144 have picked up a set of dies from the source substrate, a signal can be transmitted to the controller 160 that the picking up of the set of dies has been completed. After the array of pick-up heads 144 have transferred the set of dies 1522 to the array of bonding heads 124, a signal can be transmitted to the controller 160 that the transfer from the pick-up heads to the bonding heads has been completed.

The array of bonding heads 124 are coupled to the bridge 120. Each of the bonding heads within the array of bonding heads 124 can include a die chuck (not shown) and a body disposed between the die chuck and the bridge 120. The die chuck faces the base 140 or a component coupled to the base 140. Different design considerations may be used for the array of bonding heads 124 as compared to array of pick-up heads 144. Between the array of pick-up heads 144 and the array of bonding heads 124, the bonding heads can have the same design or a different design as compared to the pick-up heads 142.

Similar to the array of pick-up heads 144, the array of bonding heads 124 can be configured as a vector (a row or a column of bonding heads 124) or as a matrix (at least two rows and at least two columns of bonding heads 124). Regarding the matrix, the number of bonding heads within the array of bonding heads 124 may be different between rows, between columns, or between rows and columns. Some array configurations can be 3×1, 6×1, 2×2, 2×3, 2×4, 10×10, or other rectangular shape, where the first number corresponds to the number of bonding heads along a row or column, and the second number corresponds to the number of bonding heads along the other of the row or column. For such a configuration, the array of bonding heads 124 may have fewer bonding heads along rows closer to the top and bottom of the array as compared to the row closest to the center of the array, and the array of bonding heads 124 may have fewer bonding heads along columns closer to the left-hand side and right-hand side of the array as compared to the column closest to the center of the array. In an embodiment, the array of bonding heads 124 has the same number of rows and columns as compared to the array of pick-up heads 144.

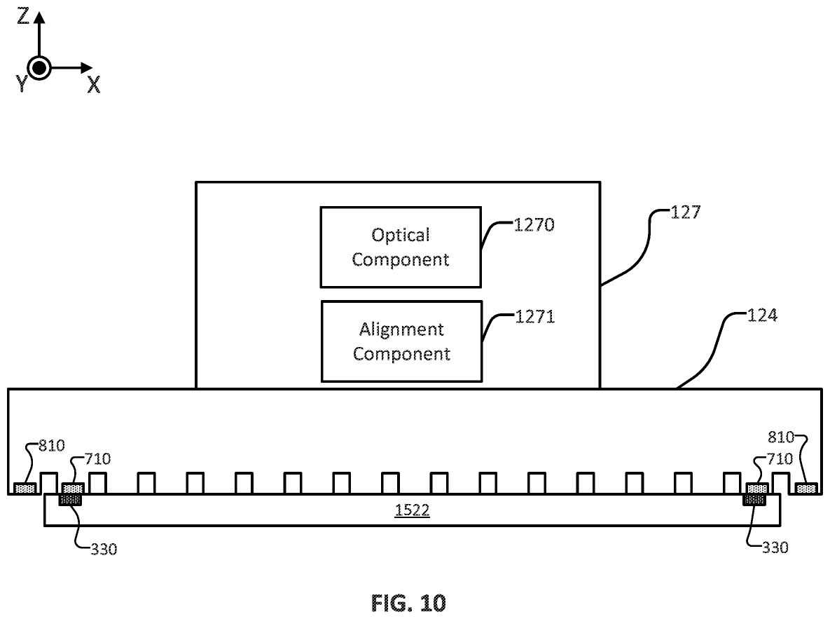

FIG. 10 is a block diagram illustrating an exemplary configuration of metrology and alignment hardware 127. The metrology and alignment hardware 127 include an optical component 1270 and alignment component 1271. The optical component 1270 can include one or more of infrared microscope and any microscope, camera and beam splitter that are capable of seeing through a die chuck of the bonding head 124. The optical component 1270 can be used for measuring the position of the bonding head alignment marks 710 and measuring the relative position of the die alignment marks 330. The die chuck of bonding head 124 may be transparent to the measurement light used by optical component 1270. The optical component 1270 may be arranged to gather light for measurement of the set of die alignment marks 330, bonding head alignment marks 710, bonding heads fiducials 810 and 910, and destination fiducials 820 and destination chuck reference marks 920.

The alignment component 1271 may include one or more alignment hardware such as an X,Y, θ stage and z-axis actuator such that of the each bonding head 124 can be moved in 1-6 axes (i.e., X, Y, Z, Pitch, Roll, Yaw) independently relative to the bridge 120 and the base 140. As shown in FIG. 10, the bonding head 124 is coupled with the metrology and alignment hardware 127. However, the metrology and alignment hardware 127 may be shared and used by more than one bonding head 124 for measurement and alignment purposes.

Returning to FIG. 1, the destination chuck 148 can be coupled to the destination carriage 146 and has a chucking surface facing the bridge 120 or a component coupled to the bridge 120. In an embodiment, the destination chuck 148 is attached to the destination carriage 146. The destination chuck 148 can hold a destination substrate 1048 having destination bonding sites. The destination chuck 148 can be a vacuum chuck, pin-type chuck, a groove-type chuck, an electrostatic chuck, an electromagnetic chuck, or the like. The destination chuck 148 can be heated, cooled, or both heated and cooled. The destination chuck 148 can include a heater. In the same or different embodiment, a fluid (not illustrated) can flow through the destination chuck 148 to increase or decrease the temperature of the destination chuck 148.

In an embodiment, the downward facing metrology and alignment hardware 127 may be used for inspecting the surface of the destination substrate 1048 to obtain the bonding positions of the die prior to bonding. In an embodiment, the upward facing metrology and alignment hardware 147 may be used for measuring and inspecting the dies 1022 on the holding substrate 1032 and the dies on the bonding head 124.

The bonding apparatus 100 can be controlled by a controller 160 in communication with the bridge 120, any component coupled to the bridge 120, the base 140, any component coupled to the base 140, or a combination thereof. The controller 160 can execute computer readable program or instructions, optionally stored in memory 162. The controller 160 can include a processor (for example, a central processing unit of a microprocessor or microcontroller), a field-programmable gate array (FPGA), an application specific integrated circuit (ASIC), or the like. The controller 160 can be within the apparatus 100. In another implementation (not illustrated), the controller 160 can be at least part of a computer external to the apparatus 100, where such computer is bidirectionally coupled to the apparatus 100. The memory 162 can include a non-transitory computer readable medium that includes instructions to carry out the actions associated with the transfer operation. In another embodiment, the bridge 120, a component coupled to the bridge 120, the base 140, or a component coupled to the base 140 can include a local controller that provides some of the functionality that would otherwise be provided by the controller 160.

The bonding apparatus 100 can be configured with some or all of the components in a different configuration. For example, all components that are illustrated in FIG. 1 as being coupled to the bridge 120 may be coupled to the base 140, and all components that are illustrated in FIG. 1 as being coupled to the base 140 can be coupled to the bridge 120. In another configuration, the source chuck 122 can be coupled to the base 140 with or without a carriage coupled between the source chuck 122 and the base 140, the array of bonding heads 124 can be coupled to the base 140 with or without a carriage coupled between the array of bonding heads 124 and the base 140, the array of pick-up heads 144 can be coupled to a carriage coupled to the bridge 120 with or without the pick-up head carriage 142 coupled between the array of pick-up heads 144 and the bridge 120, the destination chuck 148 can be coupled to the base 140 with or without the destination carriage 146 coupled between the source chuck 122 and the base 140, or a combination thereof. In the same or different configuration, the metrology and alignment hardware 127, and the metrology and alignment hardware 147 can be coupled to the bridge 120 or the base 140 as illustrated in FIG. 1. In another embodiment for the same or different configuration, the metrology and alignment hardware 127 can be coupled to the base 140, the metrology and alignment hardware 147 can be coupled to the bridge 120, or any combination thereof.

Attention is directed to methods of using the bonding apparatus 100 when transferring a set of dies or die structures from a source substrate and bonding the set of dies to destination bonding sites on a destination substrate. The methods described in more detail below can be used for dies and die structures. Die structures may include a thin die, a backing plate, and an adhesive layer between the thin die and the backing plate. For simplicity, the methods are described with respect to dies. The methods can also be used for die structures although much of the description below focuses on dies.

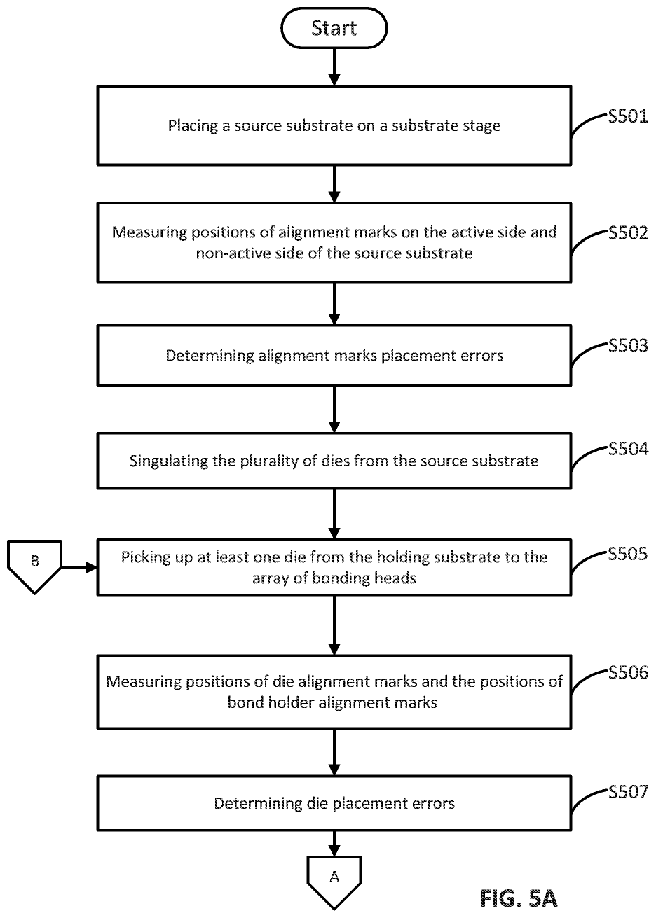

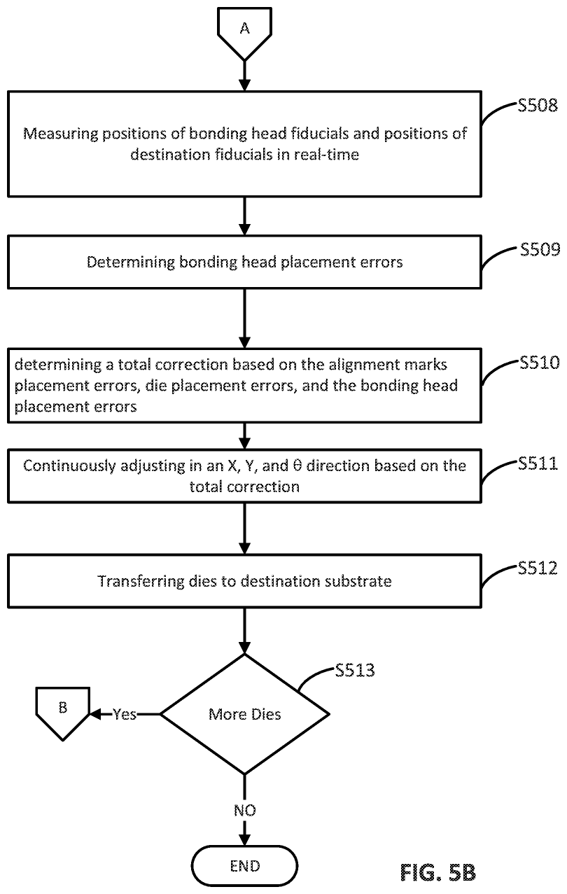

A method of transferring and bonding dies to bonding sites of a destination substrate according to an embodiment of the present disclosure will be described below with reference to FIGS. 5A and 5B. This bonding method is controlled by the controller 160. In step S501, a source substrate 1030 is placed on a substrate stage as described in FIG. 4. In this example, the source substrate 1030 of FIGS. 2A and 2B with a set of active side alignment marks 210, and a set of non-active side alignment marks 260 are used.

In step S502, metrology is performed on source substrate 1030 as described above in connection with FIG. 4 to obtain positions of alignment marks on the active side and non-active side of the source substrate 1030. the placement errors (X,Y, and θ directions) of the non-active side alignment marks 260 relative to the active side alignment marks 210. Additionally, positions of these active side marks in a global coordinate system (or source substrate coordinate system) 210 can be previously recorded from the circuit design (e.g. GDS file) or from actual measurement of their positions using another measurement tool. The measurement system 400 of FIG. 4, for example, can then provide the measurement result to the controller 160 of FIG. 1. Based on the measurement result and the expected locations of the alignment marks, a placement error model for the non-active side of the source substrate 1030 can be developed. This model or other interpolation and/or extrapolation techniques such as linear, cubic, spline, nearest neighbor, modified Akima Interpolation, etc. can be used by the controller 160 to determine the second alignment marks placement errors of the die alignment marks 330 based on the expected locations of the non-active side alignment marks 330 in a global coordinate system (or source wafer coordinate system) on the source substrate 1030 in step S503.

Upon determining the non-active side alignment marks placement error in step S503, the first substrate is singulated into a set of dies that are mounted on holding substrate 1032 without the active side alignment marks 210 and the set of corresponding non-active side alignment marks 260 in step S504. More specifically, a die singulation process is performed for dicing the source substrate 1030 into dies 1022. The source substrate 1030 including the dies can be attached to a dicing tape, and singulated into dies as previously described so as to form a holding substrate 1032 as described above. The holding substrate 1032 including the dies may then be loaded on to the source chuck 122.

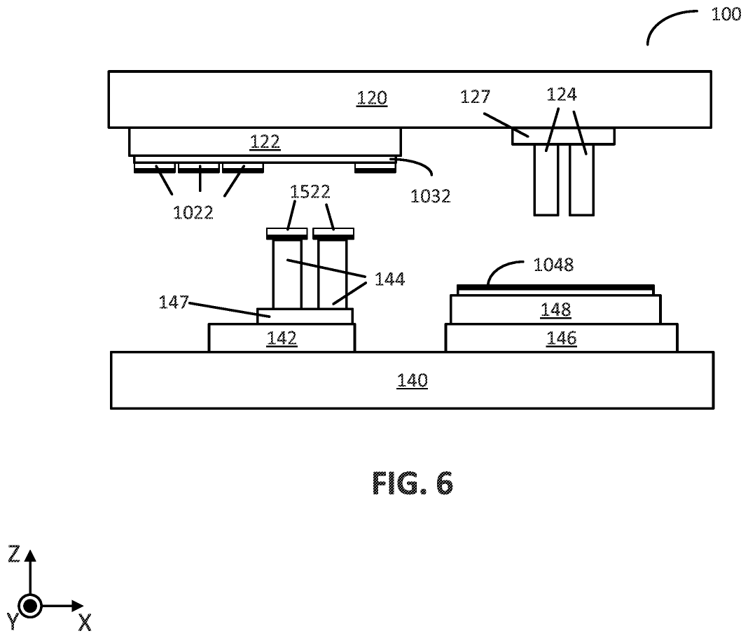

Next, as illustrated in FIG. 6, the method can include picking up a set of dies from the plurality of dies on the holding substrate in S505 in FIG. 5A. Referring to FIG. 6, the pick-up head carriage 142 may be moved to allow easier access to the source chuck 122. In one embodiment, the dies 1022 can be attached to a holding substrate 1032, and the set of dies 1522 are subsequently removed from the holding substrate 1032. Depending on predefined requirements, all or some of the dies 1022 can be transferred from the holding substrate 1032 to a destination substrate 1048. The dies 1022 can have bonding surfaces that face the base 140 or a component coupled to the base 140.

The array of pick-up heads 144 can be extended in the Z-direction and pick up the dies 1522 from holding substrate 1032 as illustrated in FIG. 6. This pick-up step may involve a metrology step to locate the relevant dies with coarse accuracy. Metrology and alignment apparatus 147 may be used to perform this metrology—for example, using the metrology and alignment hardware 147 to locate the die edges and thus, the die to be picked up. The set of dies for the transfer cycle includes the dies 1522. The method then proceeds to transfer the set of dies 1522 to the array of bonding heads 124. The pick-up head carriage 142 and destination carriage 146 are moved to the right. As such, the carriage 142 is moved so that the array of bonding heads 124 is over the array of pick-up heads 144 and the dies 1522 are transferred to bonding heads 124.

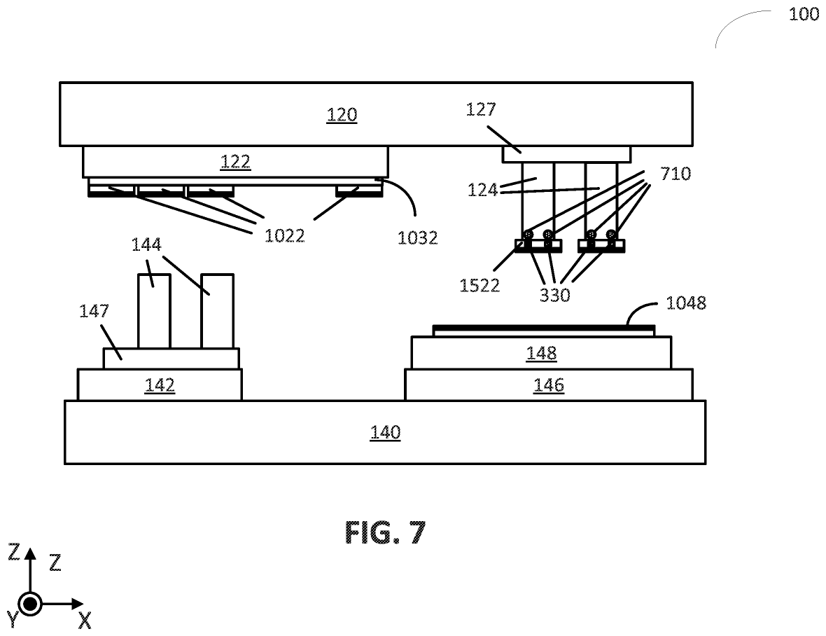

Next, after the dies 1522 are transferred to the array of bonding heads 124, the pick-up head carriage 142 and the destination carriage 146 are moved to the left. FIG. 7 shows a cross-sectional view of the bonding apparatus 100 as the metrology hardware 127 and 147 are collecting information. A set of bonding head alignment marks 710 can be located in each of the bonding heads 124. Instead of having the alignment marks in the bonding heads 124, the alignment marks may also be included in the die chucks (not shown) within the bonding heads 124. The set of die alignment marks 330 as discussed above in connection with FIG. 3 can also be located from the corresponding dies held by the bonding heads 124. Then, the metrology with respect to the bonding head alignment marks 710 and die alignment marks 330 is performed. Here, the positions of alignment marks of the bonding head alignment marks 710 and die alignment marks 330 are measured by an optical component of metrology and alignment hardware 127 and the information is subsequently provided to the controller 160. In an alternative embodiment, the metrology and alignment hardware 127 that is used to measure the position of the die on the die chuck is a part of the bonding head 124. These sets of marks-330 and 710 could be complementary Moiré interference marks of one or more two-dimensional diffraction gratings and produce interference fringes which can be detected by the optical component of metrology and alignment hardware 127. Instead of measuring the bonding head alignment marks 710 in real-time, positional information of die placement error on the bonding head or bonding chuck using alignment marks 710 and 330 may be previously registered using an off-axis metrology system and stored in the memory 162. The controller 160 may subsequently retrieve this error information for supplying the correction offsets to die-substrate motion controller to minimize the alignment errors.

In step S506, upon obtaining the measured information, the metrology hardware 127 provides the information to the controller 160 to determine the offset between the die alignment marks 330 on the non-active side of the dies and the bonding head alignment marks 710 (die placement error) as described in the following equation (S507):

$${Error}_{DiePlacement} = \{ {e}_{{x}_{dietoBH}} , {e}_{{y}_{dietoBH}} , {e}_{{θ}_{dietoBH}} \} , \qquad ( 2 )$$

where dietoBH stands for die alignment marks to bonding head alignment marks placement error. In addition, in determining die placement error, additional parameters such as the second alignment marks placement errors estimated in S503 may also be used.

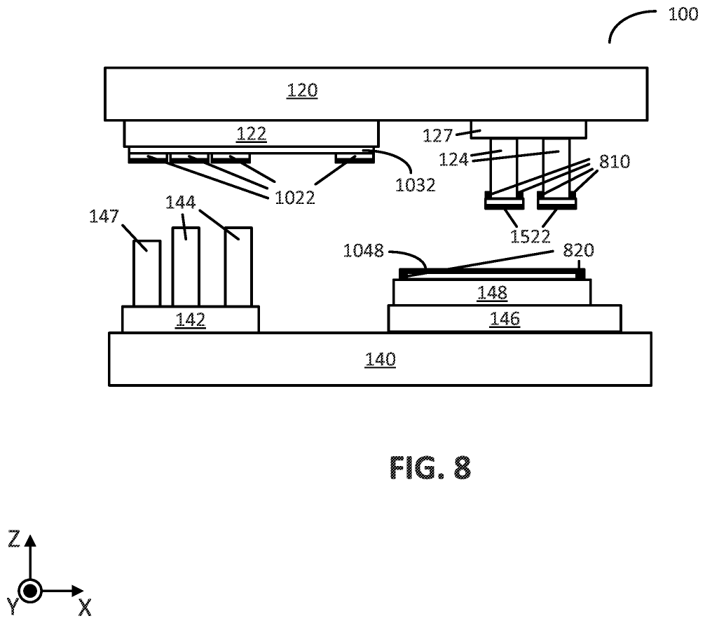

FIG. 8 illustrates a cross-sectional view of a configuration of bonding apparatus of FIG. 1 for determining bonding head alignment error relative to the substrate. In FIG. 8, for alignment purpose, bonding apparatus 100 includes bonding heads fiducials 810 on each of the bonding heads 124 and destination fiducials 820 located on destination substrate 1048. In step S508, the positional information of bonding heads fiducials 810 and destination fiducials 820 are obtained and measured by metrology hardware 127 and 147. This real-time error measurement using the destination fiducials 820 on the destination substrate 1048 and the bonding head fiducials 810 on the bonding head 124 can be completed in two ways. In one embodiment, there is a vision system or a microscope that observes the destination fiducials 820 on the destination substrate 1048 and thus, locates the destination fiducials 820 on destination substrate 1048 in the tool coordinate system. Subsequently, as the bonding head 124 is lowered to bond the die 1522 to the destination substrate 1048, the same microscope continuously observes the bonding head 124 location as it moves closer to the destination substrate 1048 and estimates the error of the bonding head fiducials 810 relative to the destination fiducials 820 in real-time using the images of the fiducials.

In another embodiment, the two sets of marks, 810 and 820 can be simultaneously imaged using the metrology and alignment hardware 127 within the same field of view to obtain the alignment error information of the bonding head relative to the substrate.

The metrology and alignment hardware 127 may be positioned or setup in a manner to accommodate both sets of fiducials, 810 and 820 so that they are within the depth of focus of the focal plane of the metrology and alignment hardware 127.

Based on the obtained information, a bonding head alignment error is determined by controller 160 based on the offset between the bonding head fiducials 810 and destination fiducials 820 in the X, Y, and 0 directions as described in the equation below:

$${Error}_{BHPlacement} = \{ {e}_{xBHtoDest} , {e}_{{y}_{BHtoDest}} , {e}_{{θ}_{BHtoDest}} \} , \qquad ( 3 )$$

where BHtoDest stands for alignment errors from bonding head to destination substrate.

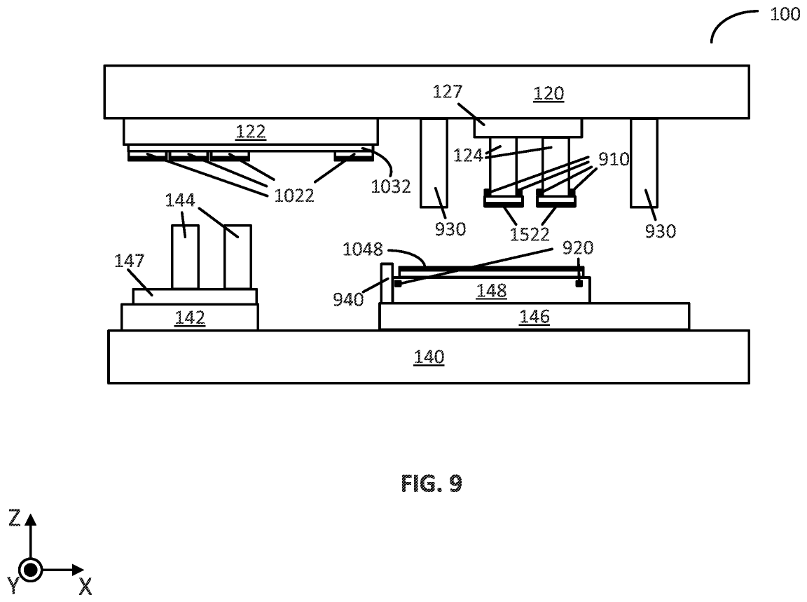

In another embodiment, as illustrated in FIG. 9, displacement sensing hardware 930 and 940 are included in the bonding system 100. Displacement sensing hardware 930 and 940 can include laser interferometer, capacitive, spectral interference sensors, infrared microscope, microscope, camera or the like thereof. The destination substrate positional information can be obtained using the displacement sensing hardware 930 and 940. For example, a microscope of displacement hardware 930 and 940 can capture the destination chuck reference marks 920 image and store the information in memory 162 as a reference. As such, the metrology of bonding head relative to the destination substrate are measured in an off-axis manner without using destination fiducials 820. In another embodiment, the displacement sensing hardware 940 locates the destination substrate 1048 and displacement sensing hardware 930 locates the bonding head 124 and the two displacement sensing hardware have been registered/calibrated to the same coordinate system and the difference between the two provides the alignment error information of the bonding head relative to the destination substrate.

The destination chuck 148 can be controlled in closed loop feedback using interferometers or any other sensors (not shown) monitoring its translations and rotations of the destination chuck 148.

Thus, when the destination substrate 1048 is moved to a desired position, together with destination chuck 148 and destination carrier 146, bonding head alignment error can be determined based on the positions of bonding head fiducials 910 and the destination chuck reference marks 920.

Next, in step S510 in FIG. 5B, a total placement error is determined based the previously obtained information from steps S503, S507, and S509 as described in the following equation:

$${Correction}_{total} ( t ) = {Error}_{AlignmentMarks 2} + {Error}_{DiePlacement} + {Error}_{BHplacement} ( t ) .$$

Upon obtaining the total correction information in the X, Y, and 0 directions, the corrections can be applied to destination chuck 148, destination carriage 146 or bonding heads 124 (step S511) prior to or in the process of transferring the dies 1522 onto destination substrate 1048. As shown in the total correction equation above, Error_{AlignmentMarks2} and ErrorDie_{Placement} are fixed values supplied as offsets to a control, and Error_{BHplacement} is a function of time and can act as the feedback signal in a feedback control loop. During the process of transferring the plurality of dies 1522 from the bonding heads 124 onto the destination substrate 1048, further movement and potential misalignment may occur. Thus, bonding apparatus 100 is capable of continuously determining the bonding head alignment error so that further adjustments and corrections can be performed in real-time to minimize alignment errors.

The alignment can be performed under the control of the controller 160 or a local controller. The alignment can be performed more than once per transfer operation and may be performed on average about one time per transfer cycle.

Then, the set of dies can be bonded to the corresponding destination bonding sites of the destination substrate 1048 at step S512 in FIG. 5B. The dies 1522 can then be bonded to corresponding destination bonding sites such as destination substrate 1048 of the destination chuck 148. The die chucks for the array of bonding heads 124 can be extended toward the destination substrate 1048, the destination chuck 148 can be extended toward the array of bonding heads 124, or both. The controller 160 or a local controller can transmit a signal for the movement of the die chucks for the array of bonding heads 124, the destination chuck 148, or both.

Pressure is exerted to bond the dies 1522 to the destination bonding sites of the destination substrate 1048 to each other. In an embodiment, the bonds can be oxide-to-oxide bonds. The pressure during bonding can be in a range 5 kPa to 200 kPa up to 2 MPa. The bonding can be performed at room temperature (for example, at a temperature in a range from 20° C. to 25° C.) or higher. Bonding is performed at a temperature less than a subsequent anneal to expand conductive metal within the dies and at the destination bonding sites. The temperature and pressure may be limited depending on films present during bonding or components within the apparatus 100. For example, the temperature may be no higher than approximately 200° C. After reading this specification, skilled artisans will be able to determine the pressure and temperature used for bonding. The controller 160 or a local controller can transmit an instruction to allow sufficient pressure to be generated for the bonding operation. At this point in the method, one transfer cycle has been completed for the set of dies that include the dies 1522.

A determination is made whether more dies are to be transferred from the source substrate to the destination substrate at decision box S513 in FIG. 5B. If more dies are to be transferred (“YES” branch), the method continues starting at step S505 in FIG. 5A with a new set of dies transferred during another transfer cycle. The method can be iterated as many times as needed for the destination substrate 1048 to have a desired number of dies. If no more dies are to be transferred (“NO” branch from decision box S512 in FIG. 5B), the transfer operation is completed, and the method of transferring dies ends. In some embodiments, multiple source substrates could be feeding into a single destination substrate. The destination substrate 1048 may then be singulated to form multiple semiconductor chips or articles.

In a hybrid bonding scenario, there are three steps in a bonding operation, a first anneal to cause the metal within the dies and at the destination bonding sites to expand and contact each other, and a second anneal to cause metal atoms to cross the metal-metal interface and reduce contact resistance. The method previously described with respect to the flow chart in FIGS. 5A and 5B and as described and illustrated in FIGS. 1, 6, 7, 8 and 9 can correspond to the bonding operation of a hybrid bonding process. The destination substrate 1048 can be removed from the apparatus 100 or moved to a different portion of the apparatus 100 or a different tool to perform the anneal operations.

Embodiments described herein allow for less force to be used when picking up dies during a die transfer operation. Embodiments can allow for less contact area between an adhesive material of a die substrate and a contacting side of a die. A gas flow rate for a Bernoulli chuck or a vacuum to be drawn when removing the die from the die substrate can be less as compared to a configuration where a convention planar substrate chuck and conventional die substrate are used. Thus, equipment in support of a Bernoulli chuck or a vacuum system used with the apparatus 100 may be less aggressively designed because it will not require a relatively larger gas flow or a relative stronger vacuum as compared to another apparatus that does not have the features or use the techniques as described herein.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc™ (BD)), a flash memory device, a memory card, and the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

What is claimed is:

1. A bonding method comprising:
providing a source substrate, the source substrate includes active side alignment marks on an active side of the source substrate, first non-active side alignment marks and second non-active side alignment marks on a non-active side of the source substrate;
obtaining positions of the active side alignment marks and positions of the first non-active side alignment marks of the source substrate; and
determining alignment marks placement errors based on offsets between the positions of the active-side alignment marks and the positions of the first non-active side alignment marks in the X, Y, and 0 directions.

2. The method according to claim 1, wherein the alignment marks placement errors is measured by an optical hardware including at least a microscope or a camera.

3. The method according to claim 1, further comprising:
singulating the source substrate to form a plurality of dies, each of the plurality of dies includes the second non-active side alignment marks;
transferring the plurality of dies to a plurality of bonding heads, each of the bonding heads includes bonding head alignment marks;
measuring positions of second non-active side alignment marks on the plurality of dies and positions of bonding head alignment marks;
estimating second alignment mark placement errors of the second non-active side alignment marks based on the alignment mark placement errors; and
determining die placement errors based on offsets between the positions of the second non-active side alignment marks and the positions of bonding head alignment marks in the X, Y, and θ directions.

4. The method according to claim 3, wherein the second non-active side alignment marks and the bonding head alignment marks are complementary Moiré interference marks.

5. The method according to claim 3, further comprising:
measuring positions of bonding head fiducials on the plurality of bonding heads and positions of destination fiducials on a destination substrate; and
determining bonding head alignment errors based on offsets between the positions of the bonding head fiducials and the positions of the destination fiducials in the X, Y, and θ directions.

6. The method of claim 5, wherein in a case where the destination fiducials are not available, the bonding head alignment errors are measured by one or more displacement sensors on the bonding head and a destination chuck.

7. The method according to claim 5, further comprising:
determining a total correction based on the second alignment marks placement errors, the die placement errors, and the bonding head alignment errors; and
adjusting the plurality of bonding heads, a destination chuck, and/or a destination carriage in an X, Y, and θ directions based on the total correction.

8. The method according to claim 7, wherein upon adjusting the plurality of bonding heads, the destination chuck, and/or the destination carriage in the X, Y, and 0 directions, the plurality of bonding heads places the plurality of dies onto the destination substrate.

9. The method of claim 8, further comprising:
processing the destination substrate using a plurality of semiconductor processes; and
singulating the destination substrate to produce a plurality of articles.

10. The method of claim 7, wherein the alignment marks placement errors and the die placement errors are fixed once the plurality of dies are transferred to the bonding heads, and the bonding head alignment errors varies while adjusting the plurality of bonding heads.

11. The method according to claim 1, wherein:
the active side alignment marks are located in unused areas of the source substrate between the plurality of dies, and
the first non-active side alignment marks are located in the unused areas of the source substrate and the first non-active side alignment marks are coincident with the active side alignment marks.

12. The method according to claim 1, wherein:
the second non-active side alignment marks are created on the non-active side of the source substrate within periphery of the plurality of dies during the same processing steps when the first non-active side alignment marks are created.

13. The method according to claim 3, wherein the die placement errors is further determined based on the second alignment marks placement errors of the one or more second non-active side alignment marks.

14. A bonding system comprising:
a stage configured to hold a source substrate, the source substrate includes active side alignment marks on an active side, first non-active side alignment marks and second non-active side alignment marks on a non-active side;
an optical hardware configured to obtain positions of the active side alignment marks and positions of the first non-active side alignment marks of the source substrate; and
a control unit configured to determine alignment marks placement errors based on offsets between the positions of the active-side alignment marks and the positions of the first non-active side alignment marks in the X, Y, and θ directions.

15. The system according to claim 14, wherein the source substrate is singulated to form a plurality of dies, and wherein each of the dies of the plurality of dies includes at least one of the second non-active side alignment marks.

16. The system according to claim 15, further comprising:
a plurality of bonding heads, wherein each of the bonding heads includes one or more bonding head alignment marks;
a plurality of pickup hardware configured to transfer the plurality of dies to the plurality of bonding heads;
a second optical hardware configured to measure positions of second non-active side alignment marks on the plurality of dies and positions of bonding head alignment marks, and provide the positions of the second non-active side alignment marks and the positions of the bonding head alignment marks to the control unit,
wherein the control unit estimates second alignment mark placement errors of the second non-active side alignment marks based on the alignment mark placement errors, and
wherein the control unit determines die placement errors based on offsets between the positions of the second non-active side alignment marks and the positions of bonding head alignment marks in the X, Y, and θ directions.

17. The system according to claim 16, wherein the bonding head alignment marks are complementary Moiré interference marks to the second non-active side alignment marks.

18. The system according to claim 16, wherein,
the second optical hardware further configured to measures positions of bonding head fiducials on the plurality of bonding heads and positions of destination fiducials on a destination substrate; and
the control unit further configured to determine bonding head alignment errors based on offsets between the positions of the bonding head fiducials and the positions of the destination fiducials in the X, Y, and θ directions.

19. The system of claim 16, wherein in a case where the destination fiducials are not available, the bonding head alignment errors are measured by one or more displacement sensors on the bonding head and a destination chuck.

20. The system according to claim 16, wherein the controller is further configured to:
determine a total correction based on the second alignment marks placement error, the die placement errors, and the bonding head alignment errors; and
providing instructions to an alignment hardware to perform adjustment of at least one of the plurality of bonding heads, a destination chuck, and/or a destination carriage in an X, Y, and θ directions based on the total correction.

21. The system according to claim 20, wherein upon adjustment of the plurality of bonding heads, the destination chuck, and/or the destination carriage in the X, Y, and 0 directions, the plurality of bonding heads places the plurality of dies onto a destination substrate.
